(19) United States
(12) Patent Application Publication
(10) Pub. No.: US 2026/0349696 A1
(43) Pub. Date: Nov. 5, 2026

(54) UPDATE EXECUTION SYSTEM, AND CONTROL DEVICE

(71) Applicant: FUJI CORPORATION, Chiryu (JP)

(72) Inventor: Junro TAKAKUWA, Toyohashi-shi (JP)

(73) Assignee: FUJI CORPORATION, Chiryu (JP)

(21) Appl. No.: 19/111,822

(22) PCT Filed: Nov. 1, 2022
(86) PCT No.: PCT/JP2022/040859

§ 371 Date: Mar. 14, 2025

(51) Int. Cl. G06F 8/65

(52) U.S. Cl. CPC G06F 8/65

(57) ABSTRACT

An update execution system includes a feeder storage configured to store multiple feeders, the feeder storage being attachable to and detachable from a mounting work machine configured to perform mounting work of an electronic component, the feeder storage being configured to supply a component from the stored feeder in a state of being attached to the mounting work machine, and a control device configured to communicate with the feeder storage in a state of being removed from the mounting work machine to update firmware of at least one of the feeder storage and the feeder stored in the feeder storage.

### TECHNICAL FIELD

The present disclosure relates to an update execution system or the like that updates firmware of at least one of a feeder storage and a feeder stored in the feeder storage.

### BACKGROUND ART

The following patent literature describes an update of firmware of a feeder.

### CITATION LIST

### Patent Literature

Patent Literature 1: WO 2022/054275

### BRIEF SUMMARY

### Technical Problem

An object of the present description is to update firmware of at least one of a feeder storage and a feeder stored in the feeder storage.

### Solution to Problem

In order to solve the above problem, the present description discloses an update execution system including: a feeder storage configured to store multiple feeders, the feeder storage being attachable to and detachable from a mounting work machine configured to perform mounting work of an electronic component, the feeder storage being configured to supply a component from the stored feeder in a state of being attached to the mounting work machine; and a control device configured to communicate with the feeder storage in a state of being removed from the mounting work machine to update firmware of at least one of the feeder storage and the feeder stored in the feeder storage.

In order to solve the above problem, the present description discloses a control device that, when a feeder storage configured to store multiple feeders is removed from a mounting work machine configured to perform mounting work of an electronic component, the feeder storage being attachable to and detachable from the mounting work machine and being configured to supply a component from the stored feeder in a state of being attached to the mounting work machine, communicates with the feeder storage in a state of being removed from the mounting work machine to update firmware of at least one of the feeder storage and the feeder stored in the feeder storage.

### Advantageous Effects

In the present description, the feeder storage configured to store the multiple feeders is attachable to and detachable from the mounting work machine configured to perform the mounting work of the electronic component and is configured to supply the component from the stored feeder in a state of being attached to the mounting work machine. In addition, the control device is configured to communicate with the feeder storage in a state of being removed from the mounting work machine to update the firmware of at least one of the feeder storage and the feeder stored in the feeder storage. Accordingly, it is possible to update the firmware of at least one of the feeder storage and the feeder stored in the feeder storage.

### BRIEF DESCRIPTION OF DRAWINGS

FIG. 1 is a perspective view showing a board work system.

FIG. 2 is a perspective view showing a mounting device and a feeder exchange device.

FIG. 3 is a perspective view showing a tape feeder.

FIG. 4 is a perspective view showing a storage rack.

FIG. 5 is a side view showing an automatic-conveyance buffer station and an automatic conveyance device.

FIG. 6 is a schematic diagram showing the board work system and a rack management device.

FIG. 7 is a perspective view showing a kitting stand.

### DESCRIPTION OF EMBODIMENTS

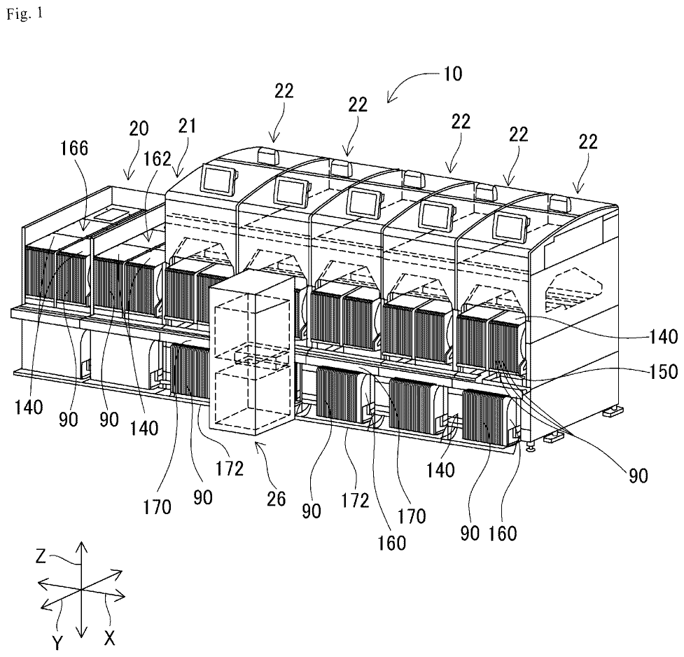

FIG. 1 shows board work system 10. System 10 shown in FIG. 1 is a system for mounting an electronic component on a circuit board. Board work system 10 includes one automatic-conveyance buffer station 20, one buffer station 21, five mounting devices 22, and one feeder exchange device 26. One automatic-conveyance buffer station 20, one buffer station 21, and five mounting devices 22 are arranged in a row in a state where one automatic-conveyance buffer station 20, one buffer station 21, five mounting devices 22 are adjacent to each other in this order. Feeder exchange device 26 is disposed on a front side (a side closer to the viewer in FIG. 1) of automatic-conveyance buffer station 20, buffer station 21, and mounting devices 22. In the following description, a direction in which automatic-conveyance buffer station 20, buffer station 21, and mounting devices 22 are arranged is referred to as an X direction, a horizontal direction perpendicular to the X direction is referred to as a Y direction, and a direction orthogonal to the X direction and the Y direction is referred to as a Z direction. Further, in the X direction, a side on which automatic-conveyance buffer station 20 is disposed is referred to as an upstream side, and a side on which mounting device 22 is disposed is referred to as a downstream side.

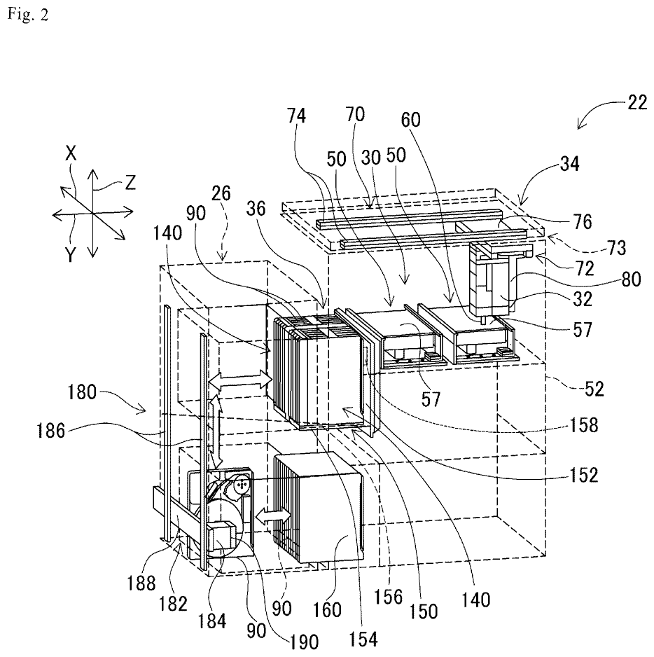

Five mounting devices 22 have substantially the same configuration as each other, and each of five mounting devices 22 includes conveyance device 30, mounting head 32, mounting head moving device (hereinafter, abbreviated as a “moving device” in some cases) 34, and supply device 36, as shown in FIG. 2.

Conveyance device 30 includes two conveyor devices 50. Two conveyor devices 50 are disposed on base 52 to extend parallel to each other and in the X direction. Each of two conveyor devices 50 conveys circuit board 57 supported by each conveyor device 50 in the X direction with an electromagnetic motor (not shown). In addition, each conveyor device 50 includes a board holding device (not shown), and fixedly holds circuit board 57 at a predetermined position.

Mounting head 32 mounts the electronic component on circuit board 57. Specifically, mounting head 32 includes suction nozzle 60 provided on a lower end surface thereof. Suction nozzle 60 communicates with a positive and negative pressure supply device (not shown) through negative pressure air and positive pressure air passages. Suction nozzle 60 picks up and holds the electronic component through a negative pressure, and separates the held electronic component through a positive pressure. Mounting head 32 includes a nozzle lifting and lowering device (not shown) that lifts and lowers suction nozzle 60. Mounting head 32 changes a position of the held electronic component in an up-down direction with the nozzle lifting and lowering device.

Moving device 34 is a device that moves mounting head 32 to any position on base 52. Specifically, moving device 34 includes X-direction slide mechanism 70 and Y-direction slide mechanism 72. Y-direction slide mechanism 72 is disposed on beam 73 suspended on base 52 and includes pair of Y-direction guide rails 74. Pair of Y-direction guide rails 74 is disposed to extend in the Y direction. Meanwhile, X-direction slide mechanism 70 includes X-direction guide rail 76, and X-direction guide rail 76 is held by pair of Y-direction guide rails 74 to extend in the X direction. Y-direction slide mechanism 72 includes an electromagnetic motor (not shown), and X-direction guide rail 76 moves to any position in the Y direction through driving of the electromagnetic motor. X-direction guide rail 76 holds slider 80 such that slider 80 is movable along an axis of X-direction guide rail 76. X-direction slide mechanism 70 includes an electromagnetic motor (not shown), and slider 80 moves to any position in the X direction through driving of the electromagnetic motor. Mounting head 32 is mounted on slider 80. With such a configuration, mounting head 32 is moved to any position on base 52 by moving device 34.

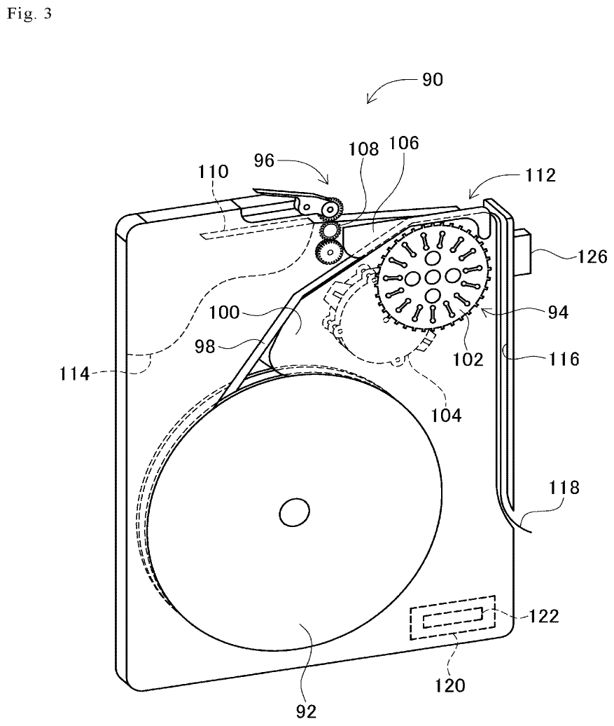

Supply device 36 is disposed at an end portion on a front side of base 52, and includes multiple tape feeders 90. As shown in FIG. 3, tape feeders 90 include reel 92, feed-out device 94, and peeling device 96, and supplies the electronic component at an end portion of an upper surface. Specifically, taped component 98 is wound on reel 92, and taped component 98 is pulled out from reel 92 onto tape guide 100. Taped component 98 is obtained by taping the electronic component, and feed holes (not shown) are formed at a predetermined pitch. Sprocket 102 of feed-out device 94 meshes with the feed holes. Sprocket 102 is rotated by electromagnetic motor 104. With such a configuration, taped component 98 is fed out toward a supply position.

In addition, peeling device 96 includes film peeling mechanism 106 and gear mechanism 108. Film peeling mechanism 106 is a mechanism for peeling top film 110 from taped component 98, and is disposed in front of opening 112 formed in an upper surface end portion of tape feeder 90. Gear mechanism 108 is a mechanism that pulls top film 110 peeled from taped component 98 into film collection section 114. With such a configuration, top film 110 is peeled from taped component 98, so that the electronic component accommodated in taped component 98 is exposed in opening 112, and the exposed electronic component is picked up and held by suction nozzle 60 of mounting head 32. That is, opening 112 is an electronic component supply position of tape feeder 90. Tape guide passage 116 is formed on a side surface of opening 112 in a feed-out direction of taped component 98 to be directed downward. Waste tape 118 obtained by extracting the electronic component from taped component 98 is discharged through tape guide passage 116. Tape feeder 90 includes control device 120, and an operation of electromagnetic motor 104 or the like is controlled in accordance with firmware 122 programmed in control device 120. Connector 126 is disposed on an end surface of tape feeder 90 in the feed-out direction of taped component 98.

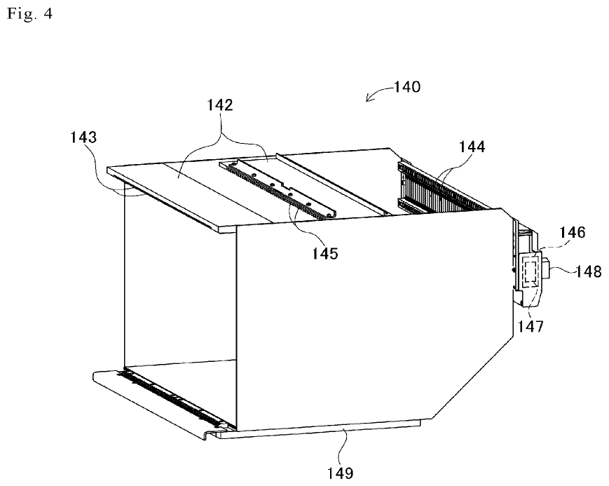

Tape feeder 90 supplies components in a state of being stored in storage rack 140 shown in FIG. 4. Specifically, storage rack 140 has a box shape in which a rear surface and an upper surface are partially open. A height dimension of an interior of storage rack 140 having the box shape is slightly larger than a height dimension of tape feeder 90, and a depth dimension of the interior of storage rack 140 is slightly larger than a depth dimension of tape feeder 90. A width dimension of the interior of storage rack 140 is larger than a width dimension of tape feeder 90 by N times (for example, 30 times). N tape feeders 90 can be stored in an arranged manner in storage rack 140 having such a shape. Multiple (N) slide grooves 143 are formed in a lower surface of top plate 142 of storage rack 140 to extend in a front-rear direction. In addition, N connector connection section 144 are formed on an inner side of the rear surface of storage rack 140 side by side in a width direction of storage rack 140.

Therefore, by fitting an upper end of tape feeder 90 into slide groove 143 and connecting connector 126 of tape feeder 90 to connector connection section 144, tape feeder 90 is stored in storage rack 140 in a positioned state and is electrically connected. Storage rack 140 includes lock mechanism 145 that locks tape feeder 90 in a stored state. Top plate 142 of storage rack 140 is open on a front side. Therefore, in tape feeder 90 stored in storage rack 140, opening 112 of tape feeder 90, that is, a component supply position is exposed from an opening of top plate 142 of storage rack 140. Storage rack 140 similarly includes control device 146, and manages tape feeder 90 stored in storage rack 140 in accordance with firmware 147 programmed in control device 146. Connector 148 is disposed on an outer side of a front surface of storage rack 140, and multiple rails 149 are disposed below a lower surface of storage rack 140 to extend in the front-rear direction.

As shown in FIG. 2, storage rack 140 is attachable to and detachable from rack holding table 150 fixedly provided at a front end portion of base 52 of mounting device 22. Rack holding table 150 includes a standing surface 152 standing in a direction perpendicular to base 52 and protruding surface 154 protruding from a lower end of standing surface 152. Multiple slide grooves 156 are formed on protruding surface 154 to extend in the Y direction, and connector connection section 158 is provided on standing surface 152. Rails 149 of storage rack 140 are fitted into slide grooves 156, and connector 148 of storage rack 140 is connected to connector connection section 158. As a result, storage rack 140 is mounted on rack holding table 150 in a positioned state and electrically connected. A dimension of rack holding table 150 in the X direction is slightly larger than twice an outer dimension of storage rack 140 in the width direction. Therefore, two storage racks 140 are mounted on rack holding table 150 side by side in the X direction. Storage rack 140 is manually attached to and detached from rack holding table 150 by a worker.

Storage case 160 is disposed below rack holding table 150. In storage case 160, multiple slide grooves (not shown) extending in the Y direction are formed side by side in the X direction, and a lower end of tape feeder 90 is detachably mounted in each slide groove.

As shown in FIG. 1, storage space 162 is formed in buffer station 21 at the same height as rack holding table 150 of mounting device 22. Storage space 162 is a space for storing storage rack 140. An inner dimension of storage space 162 in the depth direction is slightly larger than an outer dimension of storage rack 140 in the depth direction, and an inner dimension of storage space 162 in the width direction, that is, the X direction is slightly larger than twice the outer dimension of storage rack 140 in the width direction. An upper side of storage space 162 is open. Therefore, two storage racks 140 can be stored in storage space 162 side by side in the X direction.

Storage space 166 is similarly formed in automatic-conveyance buffer station 20 at the same height as rack holding table 150 of mounting device 22. Storage space 166 has substantially the same shape as storage space 162 of buffer station 21, and storage space 166 can also store two storage racks 140 side by side in the X direction.

In addition, feeder exchange device 26 performs an exchange operation of tape feeders 90 on each of automatic-conveyance buffer station 20, buffer station 21, and mounting devices 22. Specifically, upper guide rail 170 and lower guide rail 172 are disposed on front surfaces of automatic-conveyance buffer station 20, buffer station 21, and mounting devices 22 so as to extend in the X direction. Feeder exchange device 26 is held by upper guide rail 170 and lower guide rail 172 to be slidable in the X direction, and is moved to any position in the X direction through driving of an electromagnetic motor (not shown).

As shown in FIG. 2, feeder exchange device 26 includes lifting and lowering device 180, horizontal moving device 182, and clamp mechanism 184. Lifting and lowering device 180 includes pair of Z-direction guide rails 186, and pair of Z-direction guide rails 186 are disposed on a front side of rack holding table 150 and storage case 160 of mounting device 22 to extend in the Z direction. In addition, horizontal moving device 182 includes X-direction guide rail 188, and X-direction guide rail 188 is held by pair of Z-direction guide rails 186 to extend in the X direction. X-direction guide rail 188 is moved to any position in the Z direction through driving of a Z-direction motor (not shown). In addition, X-direction guide rail 188 holds clamp mechanism 184 to be movable along an axis of X-direction guide rail 188. Clamp mechanism 184 is moved to any position in the X direction through driving of an X-direction motor (not shown). In addition, clamp mechanism 184 can expand and contract in the Y direction, and expands and contracts in the Y direction through driving of an expansion and contraction motor (not shown). In addition, clamper 190 that clamps tape feeder 90 is provided at a distal end portion of clamp mechanism 184. With such a structure, feeder exchange device 26 automatically exchanges tape feeder 90 between rack holding table 150, storage case 160, and storage spaces 162 and 166.

With the configuration described above, in board work system 10, circuit board 57 is conveyed inside five mounting devices 22 by conveyance device 30, and electronic components are mounted on circuit board 57 by mounting devices 22. Specifically, first, circuit board 57 is carried into a mounting device disposed most upstream of five mounting devices 22. In the mounting device, circuit board 57 is conveyed to a working position and fixedly held at the position. Further, in storage rack 140 mounted on rack holding table 150, tape feeder 90 stored in storage rack 140 feeds out taped component 98 and supplies the electronic component at the supply position. Then, mounting head 32 moves to an upper side of the supply position of the electronic component, and picks up and holds the electronic component by using suction nozzle 60. Subsequently, mounting head 32 is moved to an upper side of circuit board 57, and mounts the held electronic component on the circuit board. When the mounting work of the electronic component on the circuit board is ended, the circuit board is conveyed downstream and is carried into the mounting device disposed downstream. The above-described mounting work is subsequently executed by each mounting device, so that the circuit board on which the electronic components are mounted is produced.

In this manner, mounting device 22 is configured to pick up and hold the electronic component supplied by tape feeder 90 by using suction nozzle 60 of mounting head 32, and mount the picked up and held electronic component on the circuit board. In mounting device 22 configured as described above, for example, tape feeder 90 of storage rack 140 held on rack holding table 150 of mounting device 22 is exchanged by feeder exchange device 26 in order to address replenishment, setup change, and the like of the electronic component. Specifically, tape feeder 90 as an exchange target is removed by clamp mechanism 184 of feeder exchange device 26 from storage rack 140 held by rack holding table 150. Then, removed tape feeder 90 is stored in storage rack 140 stored in storage space 162 or 166, or in an empty slot of storage case 160. Subsequently, a tape feeder to be mounted is clamped by clamp mechanism 184 of feeder exchange device 26 from storage rack 140 stored in storage space 162 or 166, or storage case 160. Then, tape feeder 90 clamped by clamp mechanism 184 is mounted on storage rack 140 held by rack holding table 150.

In addition, storage case 160 and storage rack 140 stored in storage space 162 of buffer station 21 basically store tape feeder 90 that accommodates an electronic component necessary for mounting work being executed by mounting device 22. Therefore, when the electronic component is replenished during the mounting work, tape feeder 90 is exchanged between storage rack 140 of rack holding table 150 and storage case 160 or between storage rack 140 of rack holding table 150 and storage rack 140 of storage space 162 of buffer station 21. Meanwhile, storage space 166 of automatic-conveyance buffer station 20 basically stores tape feeder 90 that accommodates an electronic component necessary for mounting work next to the mounting work being executed by mounting device 22 (hereinafter, referred to as a “next mounting work”). Therefore, during setup work for the next mounting work, tape feeder 90 is exchanged between storage space 166 of automatic-conveyance buffer station 20 and storage rack 140 of rack holding table 150, or between storage space 166 of automatic-conveyance buffer station 20 and storage space 162 of buffer station 21.

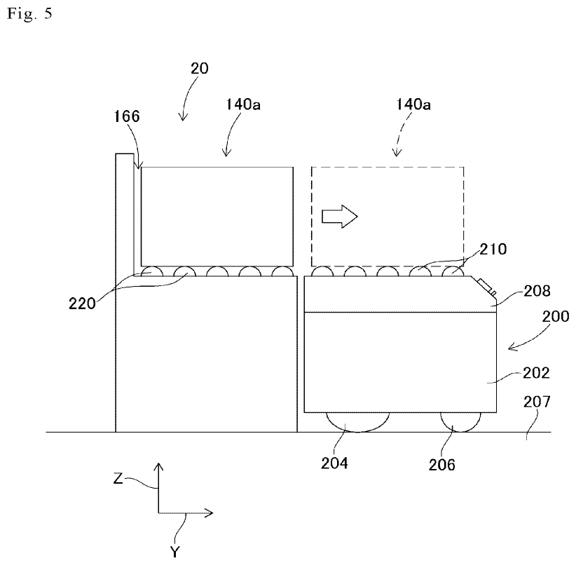

In storage space 166 of automatic-conveyance buffer station 20, storage rack 140 is automatically exchanged by automatic conveyance device 200 shown in FIG. 5. Specifically, automatic conveyance device 200 includes pair of drive wheels (only one of the pair of drive wheels is shown in the drawing) 204 and pair of steered wheels (only one of the pair of steered wheels is illustrated in the drawing) 206 disposed on a lower surface of housing 202. Thus, automatic conveyance device 200 can automatically move to any position on floor 207 on which board work system 10 is disposed. Top plate 208 is disposed on an upper surface of housing 202, and multiple conveyance rollers 210 are arranged on an upper surface of top plate 208 side by side in the front-rear direction in a posture extending in a left-right direction. Each of multiple conveyance rollers 210 is rotatable about an axis extending in the left-right direction. Multiple conveyance rollers 210 rotate in any direction through driving of an electromagnetic motor (not shown).

On a lower surface of storage space 166 of automatic-conveyance buffer station 20, multiple conveyance rollers 220 are arranged side by side in the Y direction in a posture extending in the X direction. Each of multiple conveyance rollers 220 is rotatable about an axis extending in the X direction. Multiple conveyance rollers 220 rotate in any direction through the driving of an electromagnetic motor (not shown). Upper end positions of conveyance rollers 220 of automatic-conveyance buffer station 20 and upper end positions of conveyance rollers 210 of automatic conveyance device 200 are at substantially the same height.

With such a structure, in automatic-conveyance buffer station 20, for example, storage rack 140 stored in storage space 166 is automatically transferred to automatic conveyance device 200. Specifically, automatic conveyance device 200 moves to a position facing storage space 166, in which a storage rack (hereinafter referred to as “unnecessary rack 140a”) is accommodated, by operations of drive wheels 204 and steered wheels 206. Then, multiple conveyance rollers 220 of automatic-conveyance buffer station 20 rotate in a direction in which unnecessary rack 140a is carried out, and multiple conveyance rollers 210 of automatic conveyance device 200 rotate in a direction in which unnecessary rack 140a is carried in. Accordingly, unnecessary rack 140a stored in storage space 166 is automatically transferred to automatic conveyance device 200.

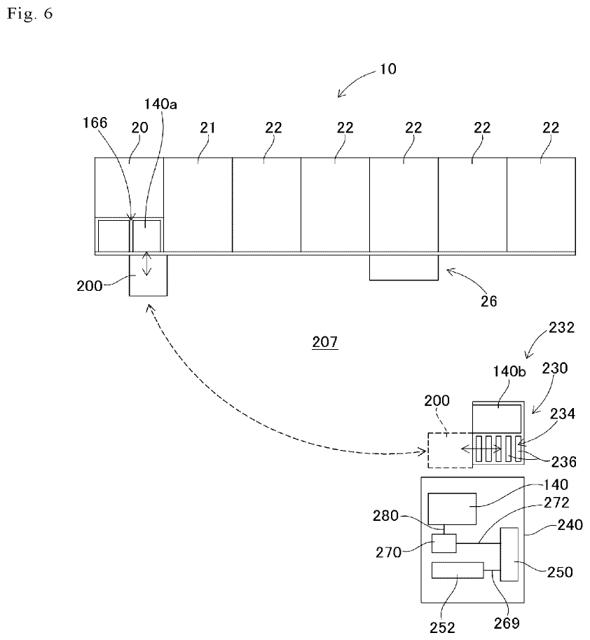

As shown in FIG. 6, rack management device 230 is also installed on floor 207 on which board work system 10 is installed. Rack management device 230 is disposed in an area different from an area in which board work system 10 is installed. In the area in which rack management device 230 is disposed, as will be described in detail later, as a part of the setup work for the next mounting work, the worker executes work of attaching reel (hereinafter, referred to as a “necessary reel”) 92 around which taped component 98 accommodating the electronic component necessary for the next mounting work is wound to tape feeder 90 and work of storing tape feeder 90 to which the necessary reel is attached in storage rack 140. Therefore, the area in which rack management device 230 is disposed is referred to as setup area 232.

Similarly to automatic-conveyance buffer station 20, rack management device 230 includes storage space 234, and can store two storage racks 140 side by side laterally in storage space 234. In rack management device 230 shown in FIG. 6, one storage rack (hereinafter referred to as “necessary rack 140b”) is stored, and tape feeder 90 to which necessary reel 92 is attached is stored in necessary rack 140b. An empty space is provided next to necessary rack 140b. Similarly to storage space 166 of automatic-conveyance buffer station 20, multiple conveyance rollers 236 are similarly arranged on a lower surface of storage space 234 of rack management device 230, and multiple conveyance rollers 236 similarly rotate in any direction through driving of an electromagnetic motor (not shown).

When unnecessary rack 140a is transferred from automatic-conveyance buffer station 20 to automatic conveyance device 200, automatic conveyance device 200 moves to a position facing an empty space of rack management device 230. Then, multiple conveyance rollers 210 of automatic conveyance device 200 rotate in a direction in which unnecessary rack 140a is carried out, and multiple conveyance rollers 236 of rack management device 230 rotate in a direction in which unnecessary rack 140a is carried in. Accordingly, unnecessary rack 140a placed on automatic conveyance device 200 is automatically transferred to storage space 234 of rack management device 230. Subsequently, automatic conveyance device 200 moves to a position facing necessary rack 140b stored in storage space 234 of rack management device 230. Then, multiple conveyance rollers 236 of rack management device 230 rotate in a direction in which necessary rack 140b is carried out, and multiple conveyance rollers 210 of automatic conveyance device 200 rotate in a direction in which necessary rack 140b is carried in. Accordingly, necessary rack 140b accommodated in rack management device 230 is automatically transferred to automatic conveyance device 200.

Next, automatic conveyance device 200 to which necessary rack 140b is transferred moves to an empty space of automatic-conveyance buffer station 20, that is, a position facing a space in which unnecessary rack 140a has been placed. Then, multiple conveyance rollers 210 of automatic conveyance device 200 rotate in a direction in which necessary rack 140b is carried out, and multiple conveyance rollers 220 of automatic-conveyance buffer station 20 rotate in a direction in which necessary rack 140b is carried in. Accordingly, necessary rack 140b placed on automatic conveyance device 200 is automatically transferred to storage space 166 of automatic-conveyance buffer station 20. In this way, unnecessary rack 140a stored in automatic-conveyance buffer station 20 is automatically exchanged with necessary rack 140b by automatic conveyance device 200.

In addition, in setup area 232, work table 240 is disposed for the worker to execute work of attaching necessary reel 92 to tape feeder 90 (hereinafter, referred to as “reel attachment work”) and work of storing tape feeder 90 to which the necessary reel is attached in storage rack 140 (hereinafter, referred to as “feeder storage work”). PC 250 and kitting stand 252 are disposed on work table 240. PC 250 stores information necessary for the reel attachment work or the like.

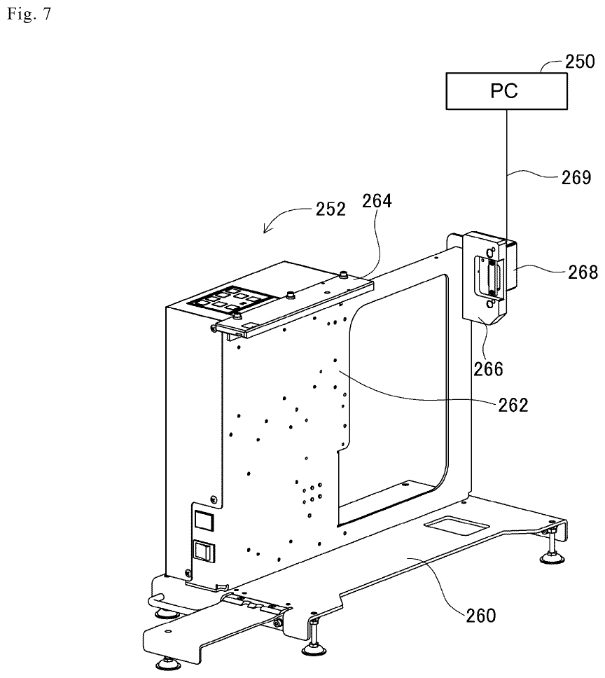

As shown in FIG. 7, kitting stand 252 includes loading table 260, stand 262, and upper rail 264. Loading table 260 supports a bottom surface of tape feeder 90, and the bottom surface of tape feeder 90 is placed on an upper surface of loading table 260. Stand 262 stands on the upper surface of loading table 260 and supports a side surface of tape feeder 90 placed on loading table 260. Upper rail 264 is disposed at an upper end portion of stand 262, and an upper end of the tape feeder 90 placed on loading table 260 is fitted to upper rail 264. Tape feeder 90 is set on kitting stand 252 in such a posture. Bracket 266 is fixed to a front side edge of stand 262 to cover a front end surface of tape feeder 90 set on kitting stand 252, and connector connection section 268 is disposed on bracket 266. Therefore, when tape feeder 90 is set on kitting stand 252, connector 126 of the tape feeder 90 is connected to connector connection section 268. Accordingly, tape feeder 90 is set in a state of being positioned on kitting stand 252 and is electrically connected.

PC 250 is connected to connector connection section 268 of kitting stand 252 via cable 269, and transmits and receives data to and from tape feeder 90 set in kitting stand 252. Tape feeder 90 on which reel 92 is not mounted is set on kitting stand 252. In addition, PC 250 stores identification information of the necessary reel as information necessary for the reel attachment work. The identification information of the necessary reel is identification information of the electronic component of taped component 98 wound around the necessary reel. PC 250 displays the identification information of the necessary reel on a monitor (not shown) of PC 250. Thus, the worker prepares reel 92 corresponding to the identification information displayed on the monitor of PC 250. A seal or the like indicating the identification information with a barcode is attached to reel 92, and the worker identifies the necessary reel through the attached seal. Then, the worker mounts the prepared necessary reel on tape feeder 90 set on kitting stand 252. Further, a barcode reader (not shown) is connected to PC 250, and the worker reads the barcode of the seal attached to the necessary reel by using the barcode reader. A seal indicating identification information of tape feeder 90 with a barcode is similarly attached to tape feeder 90, and the worker reads the barcode of the seal attached to tape feeder 90 by using the barcode reader. Then, PC 250 stores the identification information of the barcode of the necessary reel and the identification information of the barcode of tape feeder 90 which are read, in association with each other. Accordingly, in kitting stand 252, the necessary reel, that is, the reel around which taped component 98 accommodating the electronic component necessary for the next mounting work is wound is mounted on tape feeder 90, and the identification information of the necessary reel and the identification information of tape feeder 90 are stored in PC 250.

When the worker mounts the necessary reel on tape feeder 90, tape feeder 90 is stored in storage rack 140. Accordingly, tape feeder 90 configured to supply the electronic component necessary for the next mounting work is stored in storage rack 140. By repeating the mounting of the necessary reel on the tape feeder 90 and the storage of the tape feeder 90 on which the necessary reel is mounted in the storage rack 140, the reel attachment work and the feeder storage work in setup area 232 are completed. Then, storage rack 140 for which the reel attachment work and the feeder storage work are completed is stored in storage space 234 of rack management device 230 as necessary rack 140b. As described above, necessary rack 140b stored in storage space 234 of rack management device 230 is automatically stored in storage space 166 of automatic-conveyance buffer station 20 by automatic conveyance device 200.

In kitting stand 252, firmware 122 of tape feeder 90 can also be updated. Specifically, PC 250 stores a program for updating firmware 122 of tape feeder 90. Therefore, when tape feeder 90 is set in kitting stand 252, PC 250 updates firmware 122 of tape feeder 90. Accordingly, a version of firmware 122 of tape feeder 90 can be updated.

However, in kitting stand 252, only one tape feeder 90 can be set. For this reason, in order to update firmware 122 of multiple tape feeders 90, it is necessary to perform replacement of tape feeders 90 in kitting stand 252 multiple times and update firmware 122 for each tape feeder 90, which is very laborious work. Although storage rack 140 similarly includes control device 146, firmware 147 of control device 146 of storage rack 140 cannot be updated at kitting stand 252. Further, when storage rack 140 conveyed between rack management device 230 and automatic-conveyance buffer station 20 becomes an unnecessary rack, storage rack 140 is conveyed to rack management device 230, so that a time for which storage rack 140 remains in board work system 10 is short. In view of this, in setup area 232 in which rack management device 230 is disposed, the firmware of at least one of storage rack 140 and tape feeder 90 stored in storage rack 140 is updated.

Specifically, as shown in FIG. 6, control box 270 is disposed on work table 240 on which PC 250 and kitting stand 252 are disposed, and control box 270 and PC 250 are connected via cable 272. PC 250 also stores a program for updating firmware 147 of control device 146 of storage rack 140. Storage rack 140 as an update target is connected to control box 270 via cable 280. Note that cable 280 connecting storage rack 140 and control box 270 is a cable configured to communicate in a higher speed than that of cable 269 connecting PC 250 and kitting stand 252 and cable 272 connecting PC 250 and control box 270.

When storage rack 140 in which tape feeder 90 is stored is connected to control box 270 via cable 280, the firmware of both storage rack 140 and tape feeder 90 is updated. At this time, PC 250 transmits a program for updating the firmware of both storage rack 140 and tape feeder 90 and an update instruction for the firmware of both storage rack 140 and tape feeder 90 to control box 270. Control box 270 updates the firmware of both storage rack 140 and tape feeder 90. In this case, control box 270 updates the firmware of a first one of storage rack 140 and tape feeder 90, and upon completion, updates the firmware of a second one thereof. That is, for example, control box 270 first updates the firmware of storage rack 140, and upon completion of the update, updates the firmware of tape feeder 90.

When the update of the firmware of storage rack 140 is unnecessary and only the update of the firmware of tape feeder 90 is necessary, PC 250 transmits a program for updating the firmware of tape feeder 90 and an update instruction for the firmware of tape feeder 90 to control box 270. Then, control box 270 updates the firmware of tape feeder 90. Meanwhile, when the update of the firmware of tape feeder 90 is unnecessary and only the update of the firmware of storage rack 140 is necessary, PC 250 transmits a program for updating the firmware of storage rack 140 and an update instruction for the firmware of storage rack 140 to control box 270. Then, control box 270 updates the firmware of storage rack 140. Even when tape feeder 90 is attached to or detached from storage rack 140 while the firmware of storage rack 140 is being updated, the firmware of storage rack 140 is continuously updated. This is because control device 146 of storage rack 140 blocks or ignores a signal transmitted from tape feeder 90 to storage rack 140 when tape feeder 90 is attached to or detached from storage rack 140 during the update. Accordingly, during the update of the firmware of storage rack 140, tape feeder 90 can be attached to and detached from storage rack 140, and work efficiency can be increased.

When the firmware of multiple tape feeders 90 is updated in a state where multiple tape feeders 90 are stored in storage rack 140, the firmware of multiple tape feeders 90 is updated in parallel. Accordingly, it is possible to update the firmware of multiple tape feeders 90 all at once, and it is possible to improve work efficiency.

When the firmware of tape feeder 90 stored in storage rack 140 is updated, tape feeder 90 stored in storage rack 140 is locked by lock mechanism 145 of storage rack 140. Accordingly, it is possible to ensure an appropriate update of the firmware of tape feeder 90 by preventing attachment and detachment of tape feeder 90 during update.

As described above, in setup area 232 in which rack management device 230 is disposed, the firmware of at least one of storage rack 140 and tape feeder 90 stored in storage rack 140 is updated. Accordingly, it is possible to perform the update of the firmware of at least one of storage rack 140 and tape feeder 90 stored in storage rack 140 together with the setup work. Since storage rack 140 and control box 270 are connected via cable 280 for high-speed communication as described above, the update can be performed at a high speed.

Furthermore, in a related method, updating firmware for storage rack 140 or tape feeder 90 stored in storage rack 140 is executed in mounting device 22, the mounting work executed by mounting device 22 may be stopped, and productivity of board work system 10 may be reduced. That is, storage rack 140 is mounted on rack holding table 150 of mounting device 22 as described above. Therefore, in the related method, the firmware of storage rack 140 or tape feeder 90 stored in storage rack 140 is updated in a state where storage rack 140 is mounted on rack holding table 150 of mounting device 22. In such a case, since the component cannot be supplied by tape feeder 90 in mounting device 22 during the update, the mounting work executed by mounting device 22 may be stopped, and the productivity of board work system 10 may be reduced. On the other hand, when the firmware of at least one of storage rack 140 and tape feeder 90 stored in storage rack 140 is updated in setup area 232, the update can be performed without stopping the operation of mounting device 22.

In addition, in PC 250, start timings of the reel attachment work and the feeder storage work are displayed on the monitor to make it in time for the next mounting work in consideration of a time required for the reel attachment work and the feeder storage work and a time required for the update of the firmware. Specifically, for example, when the time required for the reel attachment work and the feeder storage work is 30 minutes and the time required for the update of the firmware is 30 minutes, when a start time of the next mounting work is 15:00, the start timing of the reel attachment work and the feeder storage work is displayed on the monitor at about 13:45, which is 1 hour (30 minutes+30 minutes) or more before 15:00. Accordingly, the reel attachment work, the feeder storage work, and the update of the firmware can be completed in time for the next mounting work.

In the above example, mounting device 22 is an example of a mounting work machine. Tape feeder 90 is an example of a feeder. Firmware 122 is an example of firmware. Storage rack 140 is an example of a feeder storage. Firmware 147 is an example of firmware. PC 250 is an example of a notification device. Control box 270 is an example of a control device. A system including storage rack 140 and control box 270 is an example of an update execution system.

The present disclosure is not limited to the above example, but can be carried out in various forms in which various changes and improvements are made based on the knowledge of those skilled in the art. Specifically, for example, in the above example, control box 270 and the like for updating the firmware are disposed in setup area 232, but may be disposed in various places, for example, in a place adjacent to board work system 10.

In the above example, control box 270 updates the firmware of at least one of storage rack 140 and tape feeder 90, but PC 250 may update the firmware of at least one of storage rack 140 and tape feeder 90.

In the above example, storage rack 140 is conveyed by automatic conveyance device 200, but the worker may manually carry storage rack 140.

In addition, although storage rack 140 that stores tape feeder 90 is adopted in the above example, a storage rack that accommodates various feeders such as a stick feeder and a bowl feeder as long as those are feeders may be adopted.

Further, in the above example, the start timing of the work is displayed on the monitor of PC 250, but the notification of the start timing of the work may be provided by various methods such as voice, light, and mail transmission.

In addition, in the above example, the identification information of the necessary reel and the identification information of tape feeder 90 on which the necessary reel is mounted are stored in PC 250, but the identification information of the necessary reel and the identification information of tape feeder 90 may be stored in control device 120 of tape feeder 90. In addition, the identification information of the necessary reel and the identification information of tape feeder 90 may be stored in control device 146 of storage rack 140.

It is noted that the content of the present disclosure is not limited to the dependent relationships described in the claims.

### REFERENCE SIGNS LIST

22: mounting device (mounting work machine), 90: tape feeder (feeder), 122: firmware, 140: storage rack (feeder storage) (update execution system), 147: firmware, 250: PC (notification device), 270: control box (control device) (update execution system)

1. An update execution system comprising:
a feeder storage configured to store multiple feeders, the feeder storage being attachable to and detachable from a mounting work machine configured to perform mounting work of an electronic component, the feeder storage being configured to supply a component from the stored feeder in a state of being attached to the mounting work machine; and
a control device configured to communicate with the feeder storage in a state of being removed from the mounting work machine to update firmware of at least one of the feeder storage and the feeder stored in the feeder storage.

2. The update execution system according to claim 1,
wherein the control device is configured to, when the firmware of both the feeder storage and the feeder stored in the feeder storage is updated, update the firmware of a first one of the feeder storage and the feeder stored in the feeder storage, and upon completion, update the firmware of a second one thereof.

3. The update execution system according to claim 1,
wherein the control device is configured to, when firmware of the multiple feeders stored in the feeder storage is updated, update the firmware of the multiple feeders in parallel.

4. The update execution system according to claim 1,
wherein the control device is configured to, when the firmware of the feeder storage is updated, continuously update the firmware of the feeder storage even when the feeder is attached to or detached from the feeder storage in which the update is being executed.

5. The update execution system according to claim 1,
wherein the control device is disposed in a work area for performing setup work of mounting work to be performed after mounting work being executed by the mounting work machine.

6. The update execution system according to claim 1, further comprising:
a notification device configured to provide notification of a start timing of the setup work in consideration of a time required for the setup work and a time required for the update of the firmware performed by the control device.

7. A control device that, when a feeder storage configured to store multiple feeders is removed from a mounting work machine configured to perform mounting work of an electronic component, the feeder storage being attachable to and detachable from the mounting work machine and being configured to supply a component from the stored feeder in a state of being attached to the mounting work machine, communicates with the feeder storage in a state of being removed from the mounting work machine to update firmware of at least one of the feeder storage and the feeder stored in the feeder storage.
